(19) United States
(12) Patent Application Publication
(10) Pub. No.: US 2012/0204934 A1
(43) Pub. Date: Aug. 16, 2012

(54) Bearing Based Solar Tracker

(76) Inventors: Ross Koningstein, Menlo Park, CA (US); John S. Fitch, Los Altos, CA (US); William H. Whitted, Woodside, CA (US); Zvi Gershony, San Jose, CA (US)

(21) Appl. No.: 13/025,092

(22) Filed: Feb. 10, 2011

(51) Int. Cl. F24J 2/52; H01L 31/052

(52) U.S. Cl. 136/246; 126/604

(57) ABSTRACT

A solar tracker includes a base having an upper surface, a collector support structure having a lower surface adjacent to the upper surface of the base, a conduit in fluidical communication with a space between the upper surface of the base and the lower surface of the collector support structure, a pump for pumping fluid into or out of the conduit, wherein injecting fluid into the conduit forms a fluid layer between the collector support structure and the base, and a solar collector supported by the collector support structure.

### TECHNICAL FIELD

This disclosure relates to solar trackers, e.g., heliostats or photovoltaic cell assemblies.

### BACKGROUND

Heliostats can be used in the collection of radiation from the sun. Specifically, a heliostat can include one or more mirrors to direct sunlight toward a receiver. Some types of heliostats are capable of moving their mirror or mirrors as the sun moves across the sky, both throughout the day and over the course of the year, in order to more efficiently collect sunlight and focus the sunlight on the receiver.

Solar radiation that is directed to the receiver can then be used to generate power. A field of heliostats can be placed to surround one or more receivers to increase the quantity of radiation collected and maximize the amount of power that is generated. The solar power is converted to electricity by either the receiver or a generator that is coupled to the receiver.

### SUMMARY

A simple solar tracker, e.g., a heliostat or a photovoltaic cell assembly, is described that can be formed of inexpensive materials. The solar tracker can have a fluid bearing structure that allows rotation and/or translation. The fluid bearing can be activated by supplying fluid, e.g., from a reservoir inside the solar tracker from an external channel.

In one aspect, a solar tracker includes a base having an upper surface, a collector support structure having a lower surface adjacent to the upper surface of the base, a conduit in fluidical communication with a space between the upper surface of the base and the lower surface of the collector support structure, a pump for pumping fluid into or out of the conduit, wherein injecting fluid into the conduit forms a fluid layer between the collector support structure and the base, and a solar collector supported by the collector support structure.

Implementations can include one or more of the following features. The upper surface of the base may be concave, and the support may have a convex lower surface. The lower surface of the support may be spherical or cylindrical. The upper surface of the base may be flat. The lower surface of the collector support structure may have a flat portion. The base, collector and conduit may be configured such that moving fluid into the conduit moves the support away from the base. The conduit may be a first conduit and solar tracker may further include at least a second conduit, and the first conduit and second conduit may be positioned such that selectively introducing or evacuating fluid from each of the first conduit and the second conduit moves the support. The first conduit and second conduit and support may be configured so that introducing and evacuating fluid between the support and base translates the support. The first conduit, second conduit and support are configured so that introducing and evacuating fluid between the support and base rotates the support. The solar collector may be a mirror or a photovoltaic cell. The base may have an upper surface that is at least a square foot in area, e.g., at least ten square feet in area. The solar tracker may include a brake to stop motion of the support. The brake may include an interlocking feature on each of the base and the support. The base may be cement, and the support may be plastic. The upper surface of the base may include plastic, the lower surface of the support may include plastic, and the plastic on the upper surface may contact the plastic on the lower surface. The solar tracker may include a seal between the base and the support. The fluid between the base and the support may be a bearing liquid, and the seal may be a sealing liquid that is immiscible with the bearing liquid and that floats on an upper surface of the bearing liquid. The base may include a fluid collection channel and fluid return fluidly coupled to the fluid collection channel. The fluid may include beads. The conduit may be formed through the base.

The devices described herein may provide none, one or more of the following advantages. A solar tracker that is described herein can be constructed in an inexpensive manner and of inexpensive material. This can bring down the cost of constructing a field of solar trackers, which in turn can bring down the cost of producing electricity from concentrated sunlight. Because the solar trackers are inexpensive, in the event that any particular solar tracker breaks down, it can be less expensive to manufacture a replacement solar tracker rather than to fix the broken solar tracker. In addition, the solar trackers are formed from a simple set of components. The simple set of components can further reduce manufacturing costs and can reduce operating costs. The solar trackers can be constructed on-site, that is, the solar trackers need not be entirely produced off-site and shipped to their location of operation. This can simplify the process and reduce the cost of manufacturing. Additionally on-site construction of solar tracker components can reduce shipping costs, increase opportunities for waste recycling and potentially decrease maintenance costs. Deployment of solar trackers can be expensive. Simple designs can be self contained in their operation and can avoid deployment costs.

The details of one or more embodiments are set forth in the accompanying drawings and the description below. Other features, objects, and advantages will be apparent from the description and drawings, and from the claims.

### DESCRIPTION OF DRAWINGS

FIG. 1 is a schematic cross-sectional side view of a heliostat.

FIG. 1A is a schematic cross-sectional view of a bladder to direct fluid into a recess in a heliostat.

FIG. 2 is a schematic cross-sectional side view of part of a solar tracker with a spherical support.

FIG. 3 is a schematic cross-sectional view of a rotor type support and base with a sealing component.

FIG. 4 is a schematic cross-sectional view of a rotor type support and base.

FIG. 5 is a schematic cross-sectional view of a constrained rotor type support and base.

FIG. 5A is a plan view of FIG. 5.

FIG. 6 is a schematic cross-sectional view of a constrained rotor type support and base with a floating bearing.

FIG. 7 is a schematic perspective view of a solar tracker rotor type support and base with a collector supported by a brace.

FIG. 8 is a schematic side view of an interlocking structure.

Like reference symbols in the various drawings indicate like elements.

### DETAILED DESCRIPTION

To address the need to create low priced energy, a simple solar tracker, e.g., a heliostat or a photovoltaic cell assembly, is described that can be formed of inexpensive materials. The solar tracker can have a bearing structure that allows rotation, translation or both motions to occur easily, even when parts of the solar tracker are large and heavy. The bearing is fluid based, e.g., with fluid in a gap between a fixed base and a movable collector support structure. The fluid can be introduced through the base of the solar tracker. The fluid can be either a gas or a liquid.

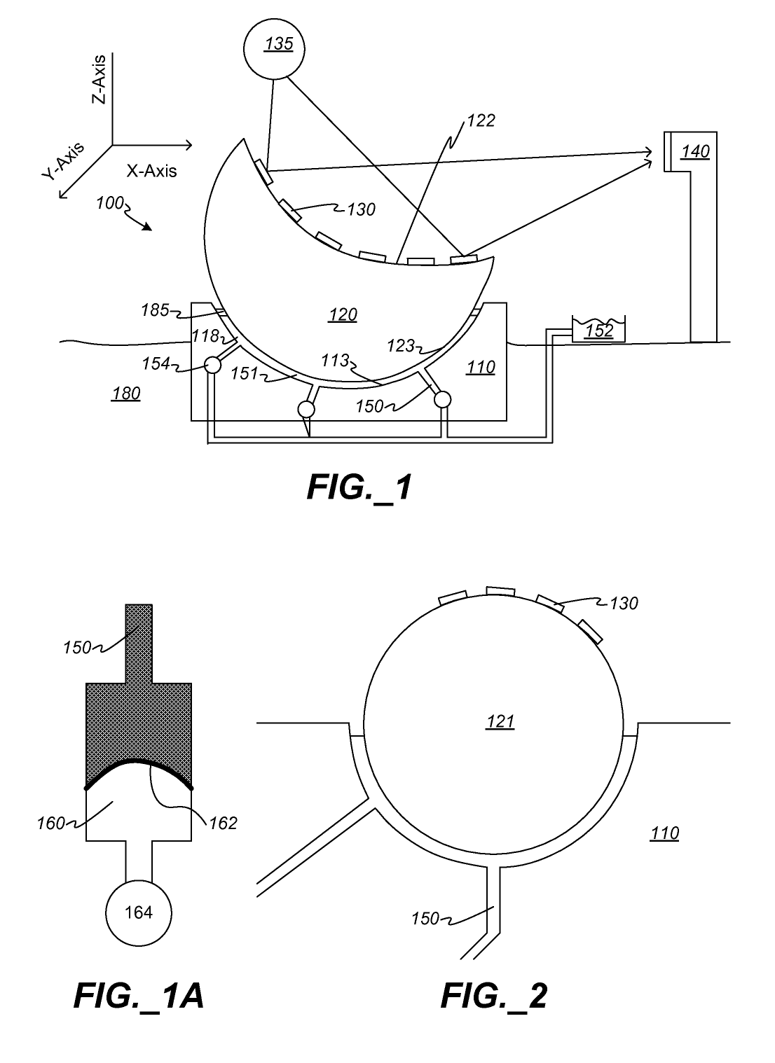

Referring to FIG. 1, a single solar tracker 100 in the form of a heliostat is shown. In some implementations, a field of heliostats is arranged for collecting radiation. However, for the sake of simplicity, in each figure only a single heliostat or portion of a heliostat is depicted. The solar tracker 100 includes a base 110 and a support structure 120. The base 110 can rest on the ground 180, and is thus generally immobile, whereas the support structure 120 is movable relative to the base 100 (and ground 180) to adjust its angle of azimuth and/or its the angle of inclination.

The support structure 120 supports one or more solar collectors 130 and thus is also referred to herein as a collector support. Assuming the solar tracker is a heliostat, each solar collector 130 can be a mirror, as shown, which receives electromagnetic radiation, e.g., visible, near infrared and near ultraviolet light, from a source, such as the sun 135, and reflects the radiation to a receiver 140. The mirrors can be formed of glass, plastic, metal or a combination thereof and shaped so as to focus the received radiation into a small cross-sectional area. The receiver 140 is configured to receive the reflected light and transform the electromagnetic radiation into electrical energy. For example, an intense concentration of electromagnetic radiation can heat air in the receiver 140, and the heated air can then expanded through a turbine engine, which turns a generator shaft to create electrical power. Alternatively, the received electromagnetic radiation can be transmitted to another component, e.g., a heat transfer component, and the electromagnetic radiation can be transformed into electrical energy through a series of intermediate steps. For example, a working fluid can be heated and transferred away from the receiver. The working fluid is then used to vaporize water to create steam, which is expanded through a turbine to generate electricity.

Alternatively, assuming the solar tracker is a photovoltaic cell assembly, each solar collector 130 can be a photovoltaic cell that converts electromagnetic radiation directly to electrical energy. The photovoltaic cells 130 create a DC output voltage, and can be connected to electrical aggregation circuitry to create a high voltage source. For example, electrical aggregation circuitry can be stationary and located on the ground 180, and can be connected to photovoltaic cells 130 by flexible electrical cabling that does not interfere with motion of the support structure 130. The high voltage source is transmitted through an arrangement of series and parallel distribution wiring. The energy that is collected can be routed to a central location for distribution to a further location.

One or more lenses or protective layers can be used in conjunction with the collectors 130, e.g., the mirrors or photovoltaic cells. As shown in FIG. 1, the collectors 130 can be on an upper surface of the support structure 120. The upper surface 122 of the support structure 120 can be a concave parabolic surface.

In the solar tracker that is shown in FIG. 1, at least a lower surface 123 of the support structure 120, i.e., on a side of the support structure opposite the upper surface 122, has a rounded surface. The rounded surface can be a convex surface, e.g., a spherical, semi-spherical, cylindrical or some other rounded shape. The surface shape depends on the type of motion that the solar tracker will make when used to track the sun. A spherical shape allows the support to move about any combination of axes sharing a common center point, while other shapes, such as cylindrical, may only allow for movement about one axis. The direction of movement can be described in terms of rotation around the x, y and z axes through the support. Thus, the spherical lower portion of the support structure allows for simultaneous rotation about each of the x, y and z axes while a cylindrical support may only allow for movement about only a single axis.

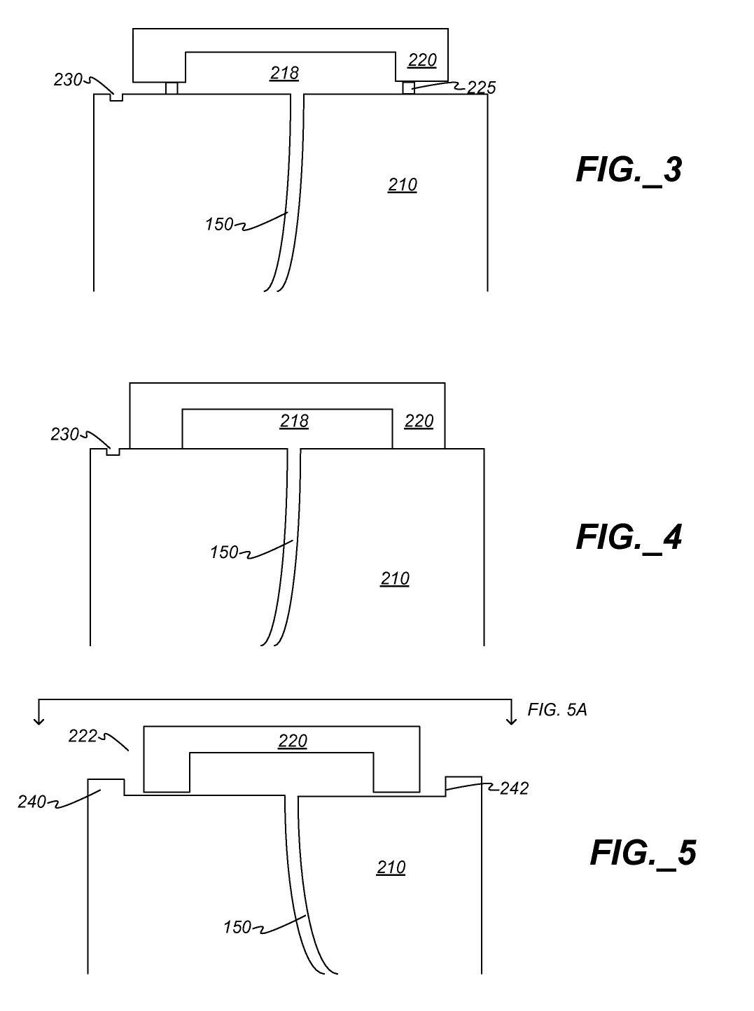

At least a portion of an upper surface 113 of the base 110, that is, the surface that is adjacent to the lower surface 123 of the support structure 120, has a shape that is complimentary to the lower surface of the support 120. The upper surface 113 can have a recess 118 that is configured to retain the support 120. That is, if the lower surface 123 of the support 120 is convex, the upper surface 113 of the base 110 is concave. Alternatively, if the lower surface of the support structure 120 is flat (as shown in FIGS. 3-5 discussed below), the upper surface of the base 110 can either be flat or can have a recess in which the support structure 120 rests.

In some implementations, when there is no fluid layer 151 between the base 110 and the support structure 120, the shape of the lower surface of the support 120 corresponds to the upper surface of the base 110 such that there are multiple points of contact between the support structure 120 and the base 110.

In some implementations, the shape and size of the recess in the base 110 and the size and shape of the complementary surface of the support structure 120 are such that a small and uniform fluid layer 151, e.g., a layer of between about 0.001 inches and 0.5 inches, can be formed in a gap between the base 110 and the support structure 120.

To be able to form the fluid layer 151, in some implementations, one or more conduits 150 are located in the base 110. The conduits are in fluid communication to a fluid supply 152. Each base 110 in a field of solar trackers can have its own fluid supply. Alternatively, there can be one or more centralized sources of fluid for supplying to a plurality of solar trackers in an array of solar trackers. Alternatively, each conduit can have its own fluid supply. A mechanism for moving fluid into or out of the recess 118 is within, on, or adjacent the base 110 and is configured to move fluid through the conduits 150. For example, each conduit 150 can be connected to its fluid supply 152 through a pump 154, which can pump fluid in either direction through the conduit, and thus force the fluid into or out of the recess 118.

Motion of the support structure 120 can be achieved by a mechanical actuator, e.g., connected between the support structure 120 and the base 110 or ground, or shifting ballast within the support structure 120. In addition, by flowing fluid into the recess through one conduit 150 and out of the recess through another conduit, a fluid flow can be established in the fluid layer 151, and this fluid flow can, e.g., by frictional interaction with the support structure, cause the support structure to move.

However, if there are other actuators associated with the solar tracker 100 only a single conduit 150 may be required to introduce fluid into or drain fluid from the base 110. The single conduit 150 can be positioned in a center of the recess to allow for effective draining of the fluid from the fluid layer 151 or effective filling of the fluid into the fluid layer 151. Alternatively, one conduit 150 can be positioned at a base of the recess, such as for draining the recess, while a second conduit 150 can be placed higher up in the recess 118.

As described above, the mechanism for moving fluid through the conduit 150 can include a pump. Alternatively or in addition, the mechanism can include a bladder, such as a bladder that is expanded to force fluid into the recess 118. Referring to FIG. 1A, the bladder can include an elastic membrane 162 to that defines an expandable volume 160, and the bladder can be connected to a pump 164 to force a fluid, such as gas, into the volume 160 defined by the bladder. As the bladder expands, the elastic membrane 162 then pushes on the fluid between the bladder and the support to move the fluid into the recess 118.

The conduits can be used to pump fluid both into and out of recess 118. For example, if too much fluid is introduced into the recess 118, due to overfilling or due to rain entering the recess 118, a conduit can be used to drain fluid from the recess 118. Alternatively, if more fluid is needed in the recess 118, such as when the recess is first filled or because of evaporation, a conduit can be used as a fluid source.

The fluid that is in fluid layer 151 can depend on the configuration of the base and the support. If the space between the base and the support can be sealed, air can be introduced between the two components to form an air bearing. The air can be compressed when used to lift the support away from the base. In some implementations, e.g., a liquid is used as the fluid layer, then gravity may be sufficient to keep the fluid from escaping from between the base and support and the seal may be necessary.

In general, suitable gases for the fluid layer 151 include air or nitrogen. Suitable liquids for the fluid layer 151 include water, oil, or gels, e.g., thixotropic gels. Ideally, the fluid is one that has a low toxicity level and would have little negative impact on the ecosystem if released from the solar tracker. The properties of the fluid, such as the viscosity, density, vapor pressure and surface tension can determine how easy or difficult it is to move the support. Thus, these properties can be optimized when selecting an appropriate fluid.

The fluid of the fluid layer 151 can be evacuated from the gap between the support structure 120 and the base 110. This lowers the support structure 120 into mechanical contact with the base 110, and thus halts the movement of the support structure 120 within the base 110 or locks the support structure 120 in position.

The solar tracker 100 is likely to be located and used outdoors. Thus, the base 110 can be placed on or buried partially in the ground 180. Because the solar tracker 100 is not located in a clean or dust-free location, it is subject to environmental dust and dirt becoming trapped between the support and the base. Particles of dirt can be carried by wind into the space between the support and base. In addition, dirt can become adhered to the support 120. Moving the support 120 may cause the particles to be introduced into the fluid layer 151 when the support is moved to where the particles are submerged in the fluid layer. Because the fluid layer 151 tends to be rather thin, particles of dust or dirt that are introduced into the fluid layer 151 can impede proper movement of the support 120. To prevent particles from entering the fluid layer, a sealing layer 185 can be on top of the fluid layer. If the fluid layer 151 is a liquid, the sealing layer 185 can be a liquid that floats on the liquid of the fluid layer 151 and is immiscible with the fluid layer 151. In some instances, the liquid of the sealing layer 185 is more viscous than the liquid of the fluid layer 151 and can trap dirt particles. The sealing layer can also prevent evaporation of the liquid of the fluid layer 151.

A filter may be employed in the flow passages external to the fluid layer 151, to filter particles from the fluid.

In order to form the solar tracker inexpensively, the components can be formed of inexpensive materials. The base 110 can be formed of cement, which may be reinforced, e.g., with steel rebar. Concrete containing an add mix of Styrofoam bead or glass micro-balloons can be used to reduce component weights and material costs. Additional chemical additives can be added to improve cure time, strength and surface qualities of the finished product. The base can be formed from a material that is malleable or moldable before being set. For example, if the base is formed of a poured cement, a mold (with a complementary projection where the recess will be formed) can be placed in the location where the recess is to be located. The mold is then removed when the cement has set and will retain its shape. The support can then be molded directly in the recess that is formed in the base to ensure corresponding shape and size of the support and base.

The conduits 150 within the base can be formed of pipes, such as plastic pipes, that are placed into the mold before the base material is poured in the mold. Alternately, the conduits 150 can be formed from the casting material during the pouring process. A mold core is placed in the mold and casting material flows around the core forming a complete conduit. When the part is cured, the mold core is removed to reveal the conduit.

The support can be formed of material that is sufficiently lightweight that it can be easily moved, but has enough mass to not be displaced, such as by high winds. In some implementations, the support is formed of a resin material. The support can then be formed from a material that can be blow molded, such as a material that results in a hard plastic. Suitable plastics can include acrylontirile butadiene styrene (ABS), polypropylene (PP), Fluoroplastics, (PTFE, FEP), Polyaryleheretherketone (PEEK), polycarbonate (PC), polyester (PE), polyethelene (HDPE, LDPE), polyphenylene oxide (PPO), polystyrene (HIPS) and polyvinyl chloride (PVC).

In some implementations, e.g., for a support formed by casting, e.g., a support formed of cement, the support can be molded directly in the recess that is formed in the base to ensure corresponding shape and size of the support and base. In some implementations, the support 110 is a container. To weight the support down, it can loaded with water, or even site gravel and dirt. The containers can be rotomolded.

Referring to FIG. 2, instead of being formed as a part of a sphere, the solar tracker 100 can include a support structure 121 that is entirely spherical. In some implementations of the spherical support, the solar collectors 130 are limited in their location on the sphere to areas that are not moved adjacent to the base 110 when the support 121 is moved. In some implementations, the solar collectors 130 are embedded into the support or positioned such that they can be moved between the base 110 and the support 121 without damaging the collectors 130.

Referring to FIGS. 3-5, the base 210 and the support structure 220 both have a substantially flat portion. The flat version of the support structure 220 can be referred to as a rotor, e.g., it is configured to permit rotary motion to change the azimuthal angle, but not the angle of inclination.

The base 210 and support structure 220 are configured so that a cavity 218 is formed between the two components. The conduit 150 is positioned in fluidical communication with the cavity 218 so that fluid can be forced into or released from the cavity 218. Although only one conduit 150 is shown in FIGS. 3-5, there can be multiple conduits 150, e.g., can be positioned at equal distances around the recess 118 of the base. The rotor can function in a manner similar to systems above; by flowing fluid into the cavity through one conduit 150 and out of the cavity through another conduit, a fluid flow can be established in the cavity 218, and this fluid flow can, e.g., by frictional interaction with the support structure, cause the support structure to move.

As shown, the base 210 has a portion that is flat and the support structure 220 has an inverted U-shape. However, other configurations are also possible. For example, the support structure 220 can have a flat surface that is adjacent to the base 210 and entirely free of recesses if there is a sealing component 225 (see FIG. 3) that allows for forming cavity 218 between the base and support. The sealing component 225 can also be used with a support having a recess therein. The sealing component 225 may be simply a piece of material that prevents fluid from escaping from between the base 210 and the support 220, but that enables or increases the ability of the support to rotate by reducing the friction between the base 210 and the support structure 220. Thus, the sealing component 225 can have a lower coefficient of friction than that of material of the support 220 contacting the material of the base 210 directly. In some implementations, between the sealing component 225 and the base 210 is a lubricating material, such as an oil, wax, smooth plastic or other material that enables the support to slide easily along the surface of the base 210 when the cavity 218 is pressurized reducing the normal force exerted on any interface between the base 210 and the support structure 220.

If the fluid introduced through conduit 150 is air, the cavity 218 can be a plenum. If the fluid introduced through conduit 150 is a liquid, the base 210 can optionally include an overflow channel 230 to catch the overflow fluid. The overflow channel 230 is optionally fluidly connected to a collection reservoir (not shown). In some implementations, the system can include the features of both the overflow channel 230 and the sealing component 225.

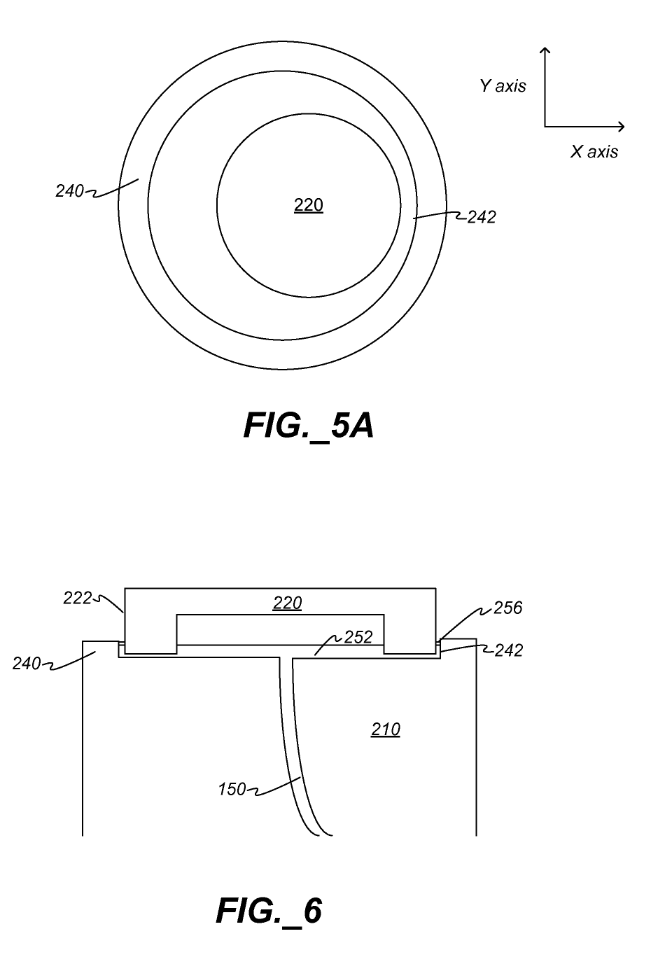

Referring to FIG. 5 and FIG. 5A, in some implementations, it is desirable to constrain the movement of the collector mirror support along one or two axes, such as along the x and the y axes. Base 210 can include a lip 240 that forms a recess in which support 220 can sit. The lip therefore has an inner diameter 242 that is greater than an outer diameter 222 of at least a lower portion of support 220. The difference between the inner diameter 242 of the lip 240 and the outer diameter 222 of the support 220 can be very small, such as less than 0.050″. For example, if the lip 240 is intended to restrain the support 220 from all transverse motion, the difference can be small. If the support 220 is to translate along the x-axis, the y-axis or both the x- and y-axes, the difference can be made to be much greater to accommodate the necessary displacements. In some implementations, the system can include the features of both the lip 240 and the overflow channel 230 and/or the sealing component 225.

The rotor can be substantially circular in plan view. Alternatively, the rotor can have another shape in plan view, such as elliptical or oval. In implementations where the base has the confining lip 240, the outer diameter 222 of the rotor can have a shape that is the same as or different from the shape of the inner diameter of the lip 240.

Referring to FIG. 6, the cavity 218 is partially or entirely filled with a liquid 252. The liquid 252 allows the support structure 220 to float. A seal 256, such as an o-ring or a layer of a sealing material, such as oil, can prevent the liquid 252 from evaporating, similar to the liquid and seal described with respect to FIG. 1. Optionally, the solar tracker has wheels or ball bearings, e.g., located on the outer surface of the support structure, e.g., to engage the lip 242, to aid in positioning of the support structure 220.

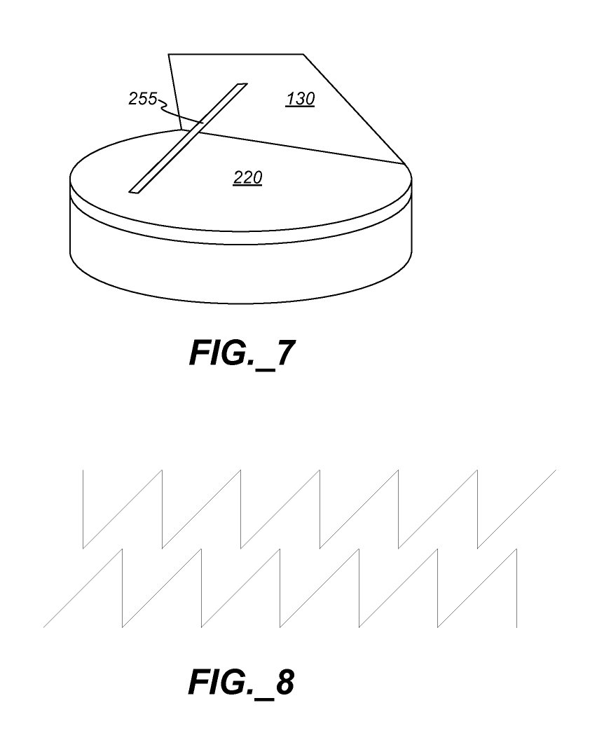

Referring to FIG. 7, the support 220 is shown supporting a collector 130. The angle at which the collector 130 is held is determined by a brace 255. In some implementations, the brace 255 is a linear actuator used to change the angle of the collector 130. For example, the brace 255 can include or be coupled to a motor that enables the brace to retract or extend, as needed. The brace 255 need not directly contact the collector 130, but can contact a secondary support for the collector or an array of collectors. Other types of collector elevators can be used to elevate or change the angle of the collector 130. Any of the rotor supports can include the support elevator, as shown in FIG. 7.

Once the support has been rotated into the desired position, the cavity 218 no longer requires pressurization. Fluid can therefore be released from the cavity 218. Depressurizing the cavity 218 can stop the motion of the support or prevent the support from moving even if more pressure is applied to the support by an actuator or another external force.

To accurately control the movement of the support 220, the support and base can include an interlocking structure, as shown in FIG. 8. The interlocking structure can be defined so that the base is only moved a predetermined amount. The interlocking structure shown is a saw tooth structure, although other interlocking structures can be used. The spacing of each tooth can determine the how much the support rotates, for example, the teeth can control the rotation to ½ milliradian. Because at least one side of a tooth of the interlocking structure is at an angle, lifting the support up to the apex of the tooth structure and allowing the support to drop is sufficient to force the support to rotate due to the interaction of the teeth in the base and the support. The interlocking structure can be located at the perimeter of the support.

In any of the implementations, the base can have a larger footprint or greater outer diameter than an outer diameter of the support. This can prevent the support from moving away from the base as it is rotated or translated.

Because the solar tracker is configured to move, a control mechanism, or controller, can be provided to control the controllable mechanisms of the solar trackers, such as fluid moving mechanisms. The controller can be a centrally located control that communicates with one or more, such as all of the solar trackers in the field. In some implementations, the controller communicates with the controllable mechanisms remotely. In some implementations, the actuators and/or fluid moving mechanisms are programmed to automatically make the necessary adjustments to the supports and the controller only periodically communicates with the controllable mechanism, such as to update the mechanisms.

A number of implementations of solar trackers have been described. Nevertheless, it will be understood that various modifications may be made without departing from the spirit and scope of the invention. For example, although the implementations described above feature conduits formed in the base, alternatively or in addition, the conduits could be formed in the support structure and the fluid could be supplied from a reservoir in the support structure through the conduits. Accordingly, other implementations are within the scope of the following claims.

What is claimed is:

1. A solar tracker, comprising:
a base having an upper surface;
a collector support structure having a lower surface adjacent to the upper surface of the base;
a conduit in fluidical communication with a space between the upper surface of the base and the lower surface of the collector support structure;
a pump for pumping fluid into or out of the conduit, wherein injecting fluid into the conduit forms a fluid layer between the collector support structure and the base; and
a solar collector supported by the collector support structure.

2. The solar tracker of claim 1, wherein:
the upper surface of the base is concave; and
the support has a convex lower surface.

3. The solar tracker of claim 2, wherein the lower surface of the support is spherical.

4. The solar tracker of claim 2, wherein the lower surface of the support is cylindrical.

5. The solar tracker of claim 1, wherein the upper surface of the base is flat.

6. The solar tracker of claim 1, wherein the lower surface of the collector support structure has a flat portion.

7. The solar tracker of claim 1, wherein the base, collector and conduit are configured such that moving fluid into the conduit moves the support away from the base.

8. The solar tracker of claim 1, wherein the conduit is a first conduit and solar tracker further comprises at least a second conduit, and the first conduit and second conduit are positioned such that selectively introducing or evacuating fluid from each of the first conduit and the second conduit moves the support.

9. The solar tracker of claim 8, wherein the first conduit and second conduit and support are configured so that introducing and evacuating fluid between the support and base translates the support.

10. The solar tracker of claim 8, wherein the first conduit, second conduit and support are configured so that introducing and evacuating fluid between the support and base rotates the support.

11. The solar tracker of claim 1, wherein the solar collector is a mirror.

12. The solar tracker of claim 1, wherein the solar collector is a photovoltaic cell.

13. The solar tracker of claim 1, wherein the base has an upper surface that is at least a square foot in area.

14. The solar tracker of claim 1, wherein the base has an upper surface that is at least ten square feet in area.

15. The solar tracker of claim 1, further comprising a brake to stop motion of the support.

16. The solar tracker of claim 15, wherein the brake includes an interlocking feature on each of the base and the support.

17. The solar tracker of claim 1, wherein the base is cement.

18. The solar tracker of claim 1, wherein the support is plastic.

19. The solar tracker of claim 1, wherein:
the upper surface of the base includes plastic and
the lower surface of the support includes plastic, wherein the plastic on the upper surface contacts the plastic on the lower surface.

20. The solar tracker of claim 1, further comprising a seal between the base and the support.

21. The solar tracker of claim 20, wherein the fluid between the base and the support is a bearing liquid and the seal is a sealing liquid that is immiscible with the bearing liquid and that floats on an upper surface of the bearing liquid.

22. The solar tracker of claim 1, wherein the base includes a fluid collection channel and fluid return fluidly coupled to the fluid collection channel.

23. The solar tracker of claim 1, wherein the fluid includes beads.

24. The solar tracker of claim 1, wherein the conduit is formed through the base.
